(19) United States
(12) Patent Application Publication
(10) Pub. No.: US 2024/0087942 A1
(43) Pub. Date: Mar. 14, 2024

(54) METHOD FOR PROCESSING SEMICONDUCTOR WAFER

(71) Applicant: ROHM CO., LTD., Kyoto-shi (JP)

(72) Inventors: Ryosuke YAMADA, Kyoto-shi (JP); Yuichi NAKAO, Kyoto-shi (JP)

(73) Assignee: ROHM CO., LTD., Kyoto-shi (JP)

(21) Appl. No.: 18/512,025

(22) Filed: Nov. 17, 2023

Related U.S. Application Data
(63) Continuation of application No. PCT/JP2022/020625, filed on May 18, 2022.

(30) Foreign Application Priority Data
May 21, 2021 (JP) 2021-085887

(51) Int. Cl. H01L 21/683; H01L 21/67; H01L 21/687

(52) U.S. Cl. CPC H01L 21/6836; H01L 21/67132; H01L 21/68721; H01L 2221/68327

(57) ABSTRACT

A method for processing a semiconductor wafer comprises: preparing a semiconductor wafer including a main body and a rim, the rim having a greater thickness than the main body and including a projection projecting; supporting the semiconductor wafer with a holding tape; preparing a base including a stage and an outer portion; setting the semiconductor wafer on the base so that the main body is supported by a support surface of the stage; and separating the main body and the rim by cutting an edge portion of the main body in a state in which the main body is supported by the stage. The setting the semiconductor wafer on the base includes setting the semiconductor wafer on the base so that the main body is supported by the stage in a state in which the projection is separated from a head surface of the outer portion of the base.

### CROSS-REFERENCE TO RELATED APPLICATIONS

The present application is a bypass continuation of International Patent Application No. PCT/JP2022/020625, filed on May 18, 2022, which corresponds to Japanese Patent Application No. 2021-085887 filed on May 21, 2021 with the Japan Patent Office, and the entire disclosure of these applications are incorporated herein by reference.

### BACKGROUND

The present disclosure relates to a method for processing a semiconductor wafer.

A semiconductor wafer, which is used to manufacture semiconductor elements such as transistors, will warp when polished and thinned. To reduce such warping, a known technique leaves the outer portion of the semiconductor wafer unpolished. When semiconductor elements are singulated from such a semiconductor wafer, the outer portion of the semiconductor wafer is cut away to form a flat semiconductor wafer before the semiconductor elements are singulated (for example, refer to Japanese Laid-Open Patent Publication No. 2013-98248).

### BRIEF DESCRIPTION OF DRAWINGS

FIG. 1 is a cross-sectional view illustrating the cross-sectional structure of a semiconductor wafer.

FIG. 2 is a plan view of a holding tape to which a frame is adhered.

FIG. 3 is a cross-sectional view taken along line 3-3 in FIG. 2.

FIG. 4 is a plan view showing the semiconductor wafer in a state supported by the holding tape.

FIG. 5 is a cross-sectional view taken along line 5-5 in FIG. 4.

FIG. 6 is a perspective view showing part of a processing device used in a process for processing the semiconductor wafer.

FIG. 7 is a plan view showing the processing device of FIG. 6.

FIG. 8 is a cross-sectional view of the processing device taken along line 8-8 in FIG. 7.

FIG. 9 is a perspective view showing the semiconductor wafer, which is supported by the holding tape, in a state set on the processing device of FIG. 6.

FIG. 10 is a cross-sectional view showing part of the semiconductor wafer, which is supported by the holding tape, in a state set on the processing device.

FIG. 11 is a perspective view illustrating a step of separating a main body and a rim of the semiconductor wafer, which is supported by the holding tape.

FIG. 12 is a cross-sectional view of FIG. 11 showing the processing device, the holding tape, the frame, and part of the semiconductor wafer.

FIG. 13 is a cross-sectional view schematically illustrating a step of separating the rim from the holding tape.

FIG. 14 is a perspective view illustrating a step of dicing the semiconductor wafer into predetermined chip dimensions.

FIG. 15 is a cross-sectional view illustrating a method for processing a semiconductor wafer in a comparative example and showing a processing device, a holding tape, a frame, and part of the semiconductor wafer.

FIG. 16 is a cross-sectional view illustrating a method for processing a semiconductor wafer in a comparative example differing from that of FIG. 15 and showing a processing device, a holding tape, a frame, and part of the semiconductor wafer.

FIG. 17 is a cross-sectional view showing the processing device, the holding tape, the frame, and part of the semiconductor wafer in a modified example of the method for processing a semiconductor wafer.

FIG. 18 is a plan view showing a base of the processing device in a modified example of the method for processing a semiconductor wafer.

FIG. 19 is a cross-sectional view showing the processing device, the holding tape, the frame, and part of the semiconductor wafer in a modified example of the method for processing a semiconductor wafer.

### DETAILED DESCRIPTION

One embodiment of a method for processing a semiconductor wafer will now be described with reference to the drawings. The embodiment described below exemplifies configurations and methods for embodying a technical concept without any intention to limit the material, shape, structure, arrangement, dimensions, and the like of each component.

### Embodiment

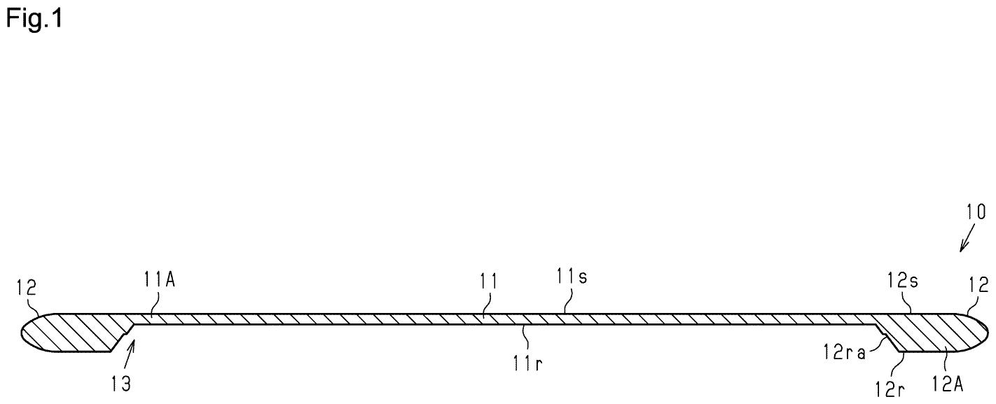

A method for processing a semiconductor wafer in accordance with the present embodiment will now be described with reference to FIGS. 1 to 14.

FIG. 1 shows the cross-sectional structure of a semiconductor wafer 10. As shown in FIG. 1, the semiconductor wafer 10 includes a main body 11 and a rim 12 surrounding the main body 11 and serving as an outer portion having a greater thickness than the main body 11. The semiconductor wafer 10 is circular as viewed in the thickness direction of the main body 11. The semiconductor wafer 10 is formed from, for example, a material containing silicon (Si). In the present embodiment, the semiconductor wafer 10 has an outer diameter of, for example, approximately 200 mm.

The semiconductor wafer 10 includes a recess 13. The recess 13 is formed by polishing a flat semiconductor wafer. This forms the main body 11 and the rim 12. The rim 12 is the part located outward from the recess 13. The main body 11 of the semiconductor wafer 10 is polished to be thinner than the rim 12. Thus, the rim 12 is thicker than the main body 11.

The main body 11 is the region where semiconductor elements such as transistors are formed. The main body 11 is circular as viewed in the thickness direction of the main body 11. The main body 11 of the semiconductor wafer 10 has a thickness of, for example, 300 μm or less. In one example, the main body 11 of the semiconductor wafer 10 has a thickness between 70 μm and 220 inclusive.

The main body 11 includes a first surface 11s and a second surface 11r at opposite sides in the thickness direction. The thickness direction of the main body 11 has the same meaning as a direction orthogonal to the first surface 11s. In the description hereafter, a view taken in a direction orthogonal to the first surface 11s will be referred to as plan view. Thus, plan view has the same meaning as the thickness direction of the main body 11.

The first surface 11s is where semiconductor elements are formed in a surface construction of a device. The first surface 11s is a flat surface. Thus, the first surface 11s defines an element formation region.

The second surface 11r is flat and includes the recess 13. The second surface 11r defines the bottom surface of the recess 13. The thickness of the main body 11 is the determined by the distance between the first surface 11s and the second surface 11r.

The rim 12 includes a projection 12A that has a greater thickness than the main body 11, surrounds the main body 11 in a looped manner as viewed in the thickness direction of the main body 11, and projects from the second surface 11r of the main body 11 opposite the first surface 11s in the thickness direction of the main body 11.

The projection 12A surrounds the main body 11 in plan view. The projection 12A is adjacent to the main body 11 in plan view. The projection 12A is ring-shaped. The projection 12A includes a first surface 12s and a second surface 12r at opposite sides in the thickness direction.

The first surface 12s faces the same direction as the first surface lis of the main body 11. In the present embodiment, the first surface 12s is partially flush with the first surface 11s.

The second surface 12r faces the same direction as the second surface 11r of the main body 11. The second surface 12r is separated from the second surface 11r of the main body 11 in plan view. The second surface 12r is separated from the second surface 11r of the main body 11 at the side opposite the first surface 11s in the thickness direction of the main body 11.

A sloped surface 12ra extends between the second surface 12r and the second surface 11r. The sloped surface 12ra connects the second surface 12r and the second surface 11r. The sloped surface 12ra forms part of the projection 12A. Further, the sloped surface 12ra forms an inner side surface of the recess 13. The sloped surface 12ra is sloped from the second surface 11r so the first surface 12s becomes farther as the second surface 12r becomes closer.

The projection 12A has a thickness determined by the distance between the first surface 12s and the second surface 12r. The thickness of the projection 12A is, for example, 500 μm or greater. In one example, the thickness of the projection 12A is between 600 and 720 μm, inclusive. The rim 12 increases the strength of the semiconductor wafer 10 and limits warping of the semiconductor wafer 10. This facilitates transportation of the semiconductor wafer 10.

The rim 12 is cut away from the semiconductor wafer 10 before dicing the semiconductor wafer 10 into predetermined chip dimensions. In the present embodiment, the method for processing the semiconductor wafer 10 includes a semiconductor wafer preparing step, a tape adhering step, a base preparing step, a setting step, a cutting step, a removing step, and a singulating step. Each step will now be described in detail.

Semiconductor Wafer Preparing Step

The semiconductor wafer preparing step prepares the semiconductor wafer 10 shown in FIG. 1. In the semiconductor wafer preparing step, the semiconductor wafer 10 may be prepared by procuring the semiconductor wafer 10 or by polishing a semiconductor substrate to form the semiconductor wafer 10.

Tape Adhering Step

The tape adhering step is performed after the semiconductor wafer preparing step. In the tape adhering step, a dicing tape 20 that is adhered to a frame 30 is first prepared. The dicing tape 20 is one example of a holding tape.

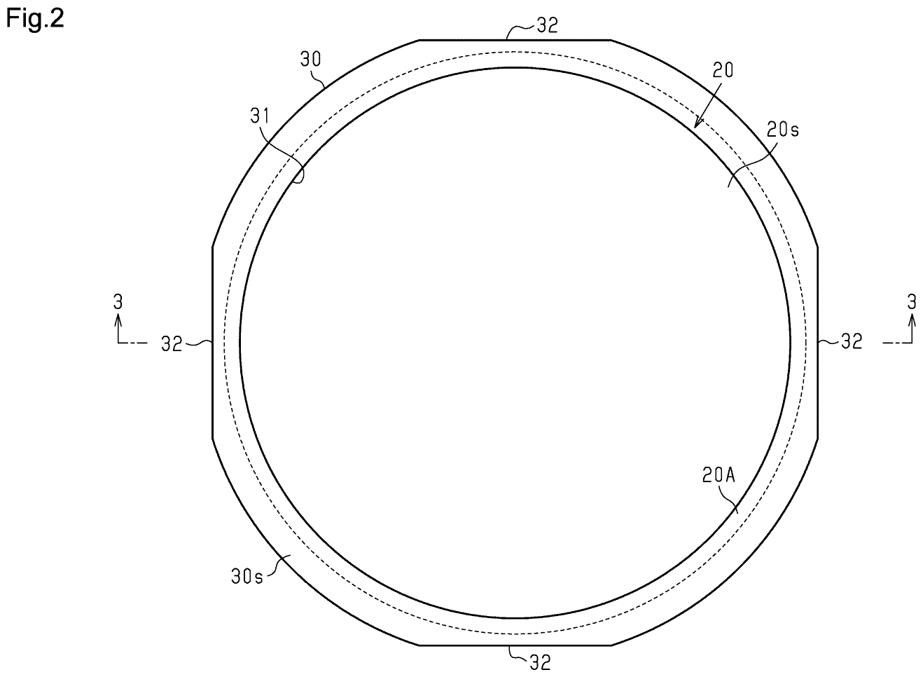

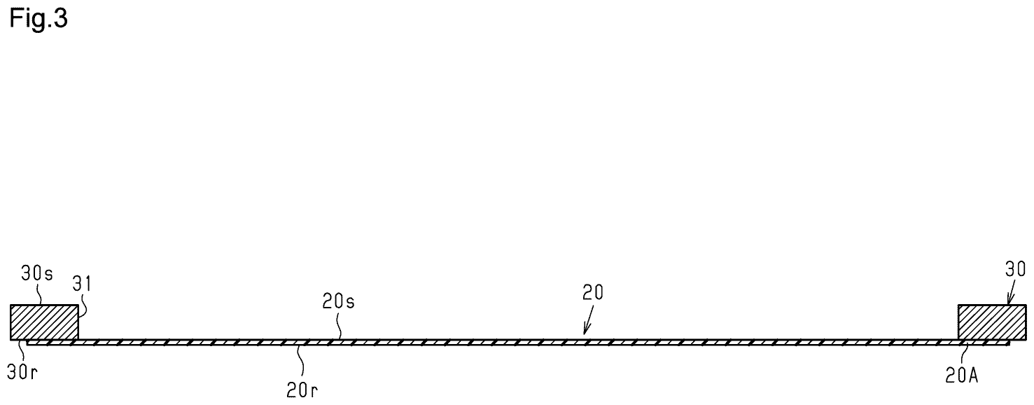

As shown in FIG. 2, the frame 30 is looped in plan view. The frame 30 is a flat plate including an open portion 31. The open portion 31 is circular in plan view. In the present embodiment, the outer edge of the frame 30 includes four flat portions 32. The four flat portions 32 are arranged at equal intervals about the center of the frame 30 in a circumferential direction. As shown in FIG. 3, the frame 30 includes a first surface 30s and a second surface 30r at opposite sides in the thickness direction.

As shown in FIG. 2, the dicing tape 20 is adhered to the frame 30 so as to cover the open portion 31 of the frame 30. The dicing tape 20 is circular in plan view. The dicing tape 20 includes an edge portion 20A adhered to an inner edge of the frame 30. The edge portion 20A forms the outer circumferential end of the dicing tape 20. The edge portion 20A of the dicing tape 20 is fixed to the frame 30. The dicing tape 20 is formed from a flexible material. As shown in FIG. 3, the dicing tape 20 includes a first surface 20s and a second surface 20r at opposite sides in the thickness direction. In the present embodiment, the dicing tape 20 is adhered to the frame 30 with the first surface 20s of the dicing tape 20 contacting the second surface 30r of the frame 30. The first surface 20s of the dicing tape 20 defines an adhesive tape surface. The first surface 30s of the frame 30 faces the same direction as the first surface 20s of the dicing tape 20. The thickness direction of the frame 30 coincides with the thickness direction of the dicing tape 20. In the present embodiment, the frame 30 is thicker than the dicing tape 20. The frame 30 has a thickness of, for example, approximately 1.2 mm.

In the adhering step, the dicing tape 20 is then adhered to the second surface 11r of the main body 11 of the semiconductor wafer 10 (refer to FIG. 1). In one example, the semiconductor wafer 10 is set in a chamber (not shown), and the chamber is then evacuated. In this state, the dicing tape 20, to which the frame 30 is adhered, is adhered to the second surface 11r of the main body 11. Then, the chamber is opened and returned to atmospheric pressure.

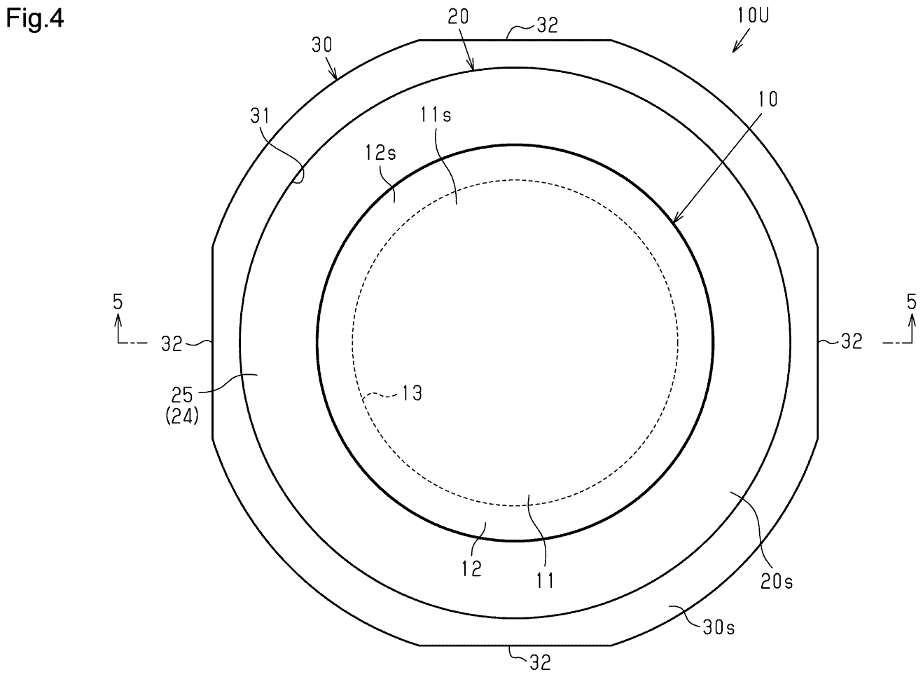

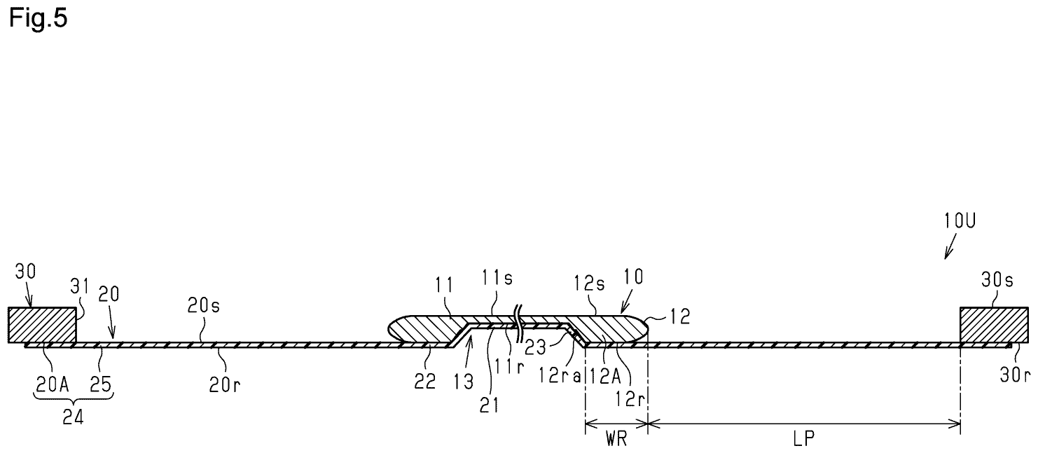

FIGS. 4 and 5 show the dicing tape 20, to which the frame 30 is adhered, in a state adhered to the second surface 11r of the main body 11 of the semiconductor wafer 10.

As shown in FIG. 4, the semiconductor wafer 10 is arranged in the open portion 31 of the frame 30 in plan view. In other words, the frame 30 surrounds the semiconductor wafer 10. The inner wall of the frame 30 includes an inner wall shaped and sized to allow for accommodation of the semiconductor wafer 10. The semiconductor wafer 10 is arranged on the first surface 20s of the dicing tape 20.

As shown in FIG. 5, the dicing tape 20 is deformed to extend into the recess 13 of the semiconductor wafer 10. The semiconductor wafer 10 is supported by the dicing tape 20, to which the frame 30 is adhered. Thus, the tape adhering step adheres the dicing tape 20 (holding tape) to the second surface 11r of the semiconductor wafer 10 in order to support the semiconductor wafer 10. The step of supporting the semiconductor wafer 10 with the dicing tape 20 includes supporting the semiconductor wafer 10 with the dicing tape 20 that is fixed to the frame 30.

The dicing tape 20 is adhered to the semiconductor wafer 10 at the second surface 11r of the main body 11 and the second surface 12r of the rim 12. The first surface 20s of the dicing tape 20 is adhered to the second surface 11r of the main body 11 and the second surface 12r of the rim 12. The dicing tape 20 does not have to be applied to the sloped surface 12ra of the rim 12 of the semiconductor wafer 10. In this manner, the dicing tape 20 includes a main body adhering portion 21, which is adhered to the main body 11, and a rim adhering portion 22, which is adhered to the rim 12. Further, the dicing tape 20 includes a sloped portion 23 connecting the main body adhering portion 21 and the rim adhering portion 22.

The main body adhering portion 21 is adhered to the second surface 11r of the main body 11 of the semiconductor wafer 10. The rim adhering portion 22 is adhered to the second surface 12r of the projection 12A at the rim 12 of the semiconductor wafer 10. The rim adhering portion 22 is separated from the main body adhering portion 21 at the side opposite the first surface 11s of the main body 11. The sloped portion 23 is sloped from the second surface 11r of the main body 11 toward the second surface 12r of the rim 12 as the sloped portion 23 extends from the main body adhering portion 21 toward the rim adhering portion 22.

The dicing tape 20 includes an extended portion 24 extending outward from the outer edge of the semiconductor wafer 10 as viewed in the thickness direction. The extended portion 24 extends from the entire circumferential edge of the semiconductor wafer 10. The extended portion 24 includes a tape outer portion 25 that is the part between the outer edge of the semiconductor wafer 10 and the frame 30 in the radial direction of the dicing tape 20. As shown in FIG. 4, the tape outer portion 25 is exposed from both the semiconductor wafer 10 and the frame 30 in plan view. In the present embodiment, the extended portion 24 includes the tape outer portion 25 and the edge portion 20A of the dicing tape 20. As shown in FIG. 5, the edge portion 20A of the dicing tape 20 is the part of the dicing tape 20 overlapping the frame 30.

As shown in FIG. 5, in the present embodiment, the tape outer portion 25 of the dicing tape 20 has a radial length LP that is greater than a width WR of the rim 12. The radial length LP of the tape outer portion 25 is the distance of the dicing tape 20 between the outer edge of the semiconductor wafer 10 and the inner wall of the frame 30 in the radial direction of the dicing tape 20 in plan view. The width WR of the rim 12 is the length of the rim 12 in the radial direction of the semiconductor wafer 10 in plan view. In the present embodiment, the frame 30 is thicker than the rim 12 of the semiconductor wafer 10. The inner diameter of the frame 30 is, for example, approximately 250 mm. Thus, the radial length LP of the tape outer portion 25 of the dicing tape 20 is, for example, approximately 25 mm. The dicing tape 20, to which the frame 30 is fixed, is adhered to the semiconductor wafer 10 in the tape adhering step. In the description hereafter, the semiconductor wafer 10 obtained through the tape adhering step is referred to as the wafer unit 10U.

Base Preparing Step

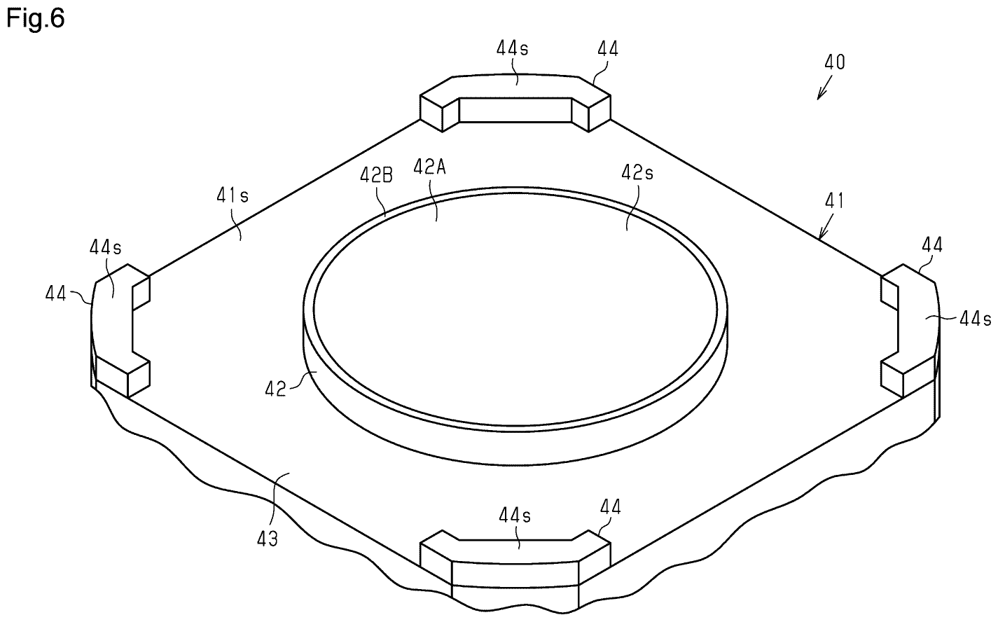

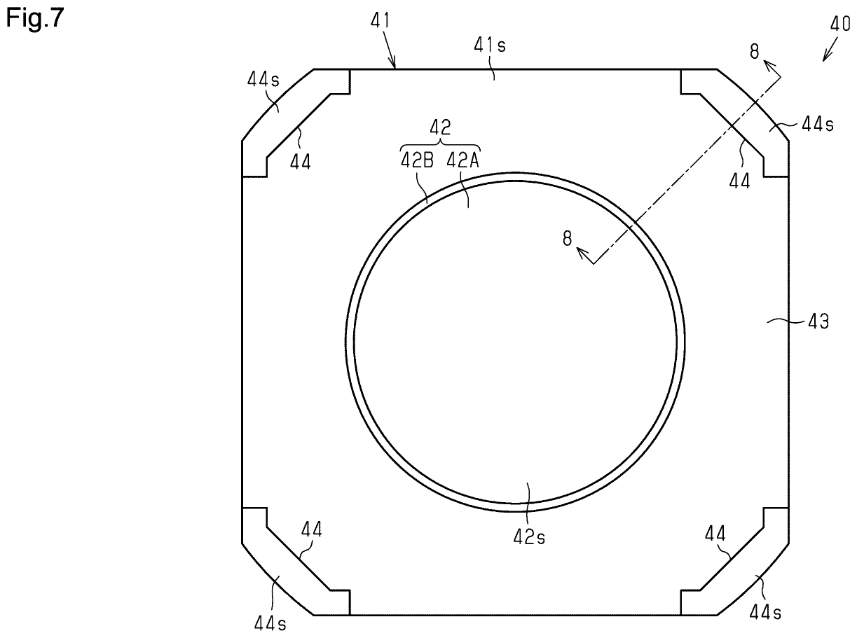

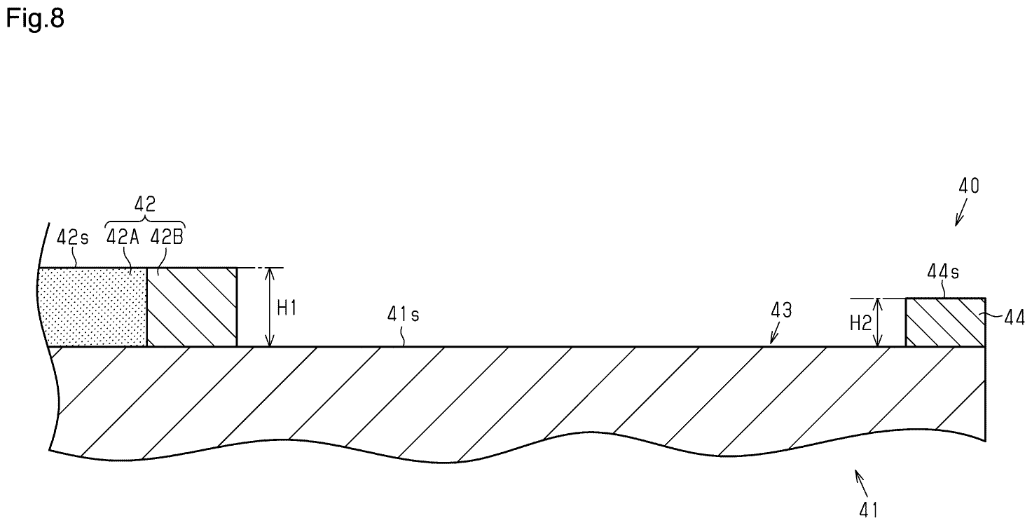

The base preparing step prepares a processing device 40 that performs a setting step and a cutting step. FIGS. 6 and 7 show one example of the processing device 40 that performs the setting step and the cutting step. FIG. 8 is a cross-sectional view showing the cross-sectional structure of the processing device 40 taken along line 8-8 in FIG. 7.

As shown in FIGS. 6 and 7, the processing device 40 includes a base 41 on which the wafer unit 10U (refer to FIG. 4) is set. The base 41 includes a stage 42, which supports the wafer unit 10U, and an outer portion 43, which is located outward from the stage 42. In the present embodiment, the outer portion 43 of the base 41 allows spacers 44, which have a predetermined thickness, to be set thereon. More specifically, the spacers 44 are attached to the outer portion 43 at predetermined positions.

The base 41 is rectangular and has four rounded corners. The base 41 includes the stage 42 and the spacers 44. The base 41 includes a head surface 41s. The head surface 41s of the base 41 includes the surface of the outer portion 43. In the present embodiment, the head surface 41s of the base 41 faces the upper vertical direction.

The stage 42 is located at the central part of the base 41, and the spacers 44 are located at the outer part of the base 41. The spacers 44 are distanced outwardly from the stage 42.

The stage 42 includes a support surface 42s. The support surface 42s faces the same direction as the head surface 41s of the base 41. The support surface 42s of the stage 42 is where the semiconductor wafer 10 is set on. The support surface 42s of the stage 42 supports the semiconductor wafer 10. When the semiconductor wafer 10 is set on the support surface 42s, the semiconductor wafer 10 is supported by the stage 42.

The stage 42 is circular as viewed in a direction orthogonal to the head surface 41s of the base 41 (i.e., in plan view). The stage 42 includes a suction portion 42A and a surrounding portion 42B.

The suction portion 42A is formed from, for example, a porous material. When the semiconductor wafer 10 is set on the suction portion 42A, an aspirator, which is arranged in the base 41, suctions the semiconductor wafer 10 onto the suction portion 42A. The suction portion 42A is circular in plan view. The suction portion 42A occupies most of the stage 42.

The surrounding portion 42B surrounds the suction portion 42A. The surrounding portion 42B is ring-shaped in plan view. The surrounding portion 42B is formed from, for example, a metal material. The upper surface of the surrounding portion 42B is flush with the upper surface of the suction portion 42A (refer to FIG. 8). The upper surface of the surrounding portion 42B and the upper surface of the suction portion 42A form the support surface 42s of the stage 42.

In the present embodiment, the spacers 44 are formed at spaced intervals. More specifically, there are four spacers 44 in the present embodiment. The spacers 44 are arranged at intervals about the center of the head surface 41s of the base 41 in the circumferential direction. The spacers 44 are located at the four corners of the base 41. In the present embodiment, each spacer 44 is separate from the base 41 and attached to the head surface 41s of the base 41. Nevertheless, each spacer 44 may be formed integrally with the base 41.

As shown in FIG. 8, the stage 42 and the spacer 44 both rise from the base 41. The stage 42 and the spacer 44 both project upward from the head surface 41s of the base 41. In other words, the head surface 41s of the base 41 is located at a lower position than the support surface 42s of the stage 42. Thus, the outer portion 43 includes a surface at a lower position than the support surface 42s of the stage 42.

In the present embodiment, a height H2 of an upper surface 44s of each spacer 44 from the base 41 is lower than a height H1 of the support surface 42s of the stage 42 from the base 41. The height H2 of the upper surface 44s of the spacer 44 is the difference between the position of the head surface 41s of the base 41 and the position of the upper surface 44s of the spacer 44 in the vertical direction. The height H1 of the support surface 42s of the stage 42 is the difference between the position of the head surface 41s of the base 41 and the position of the support surface 42s of the stage 42 in the vertical direction. In the present embodiment, the height H1 of the support surface 42s of the stage 42 is 5.5 mm, and the height H2 of the upper surface 44s of the spacer 44 is 4.8 mm.

Setting Step

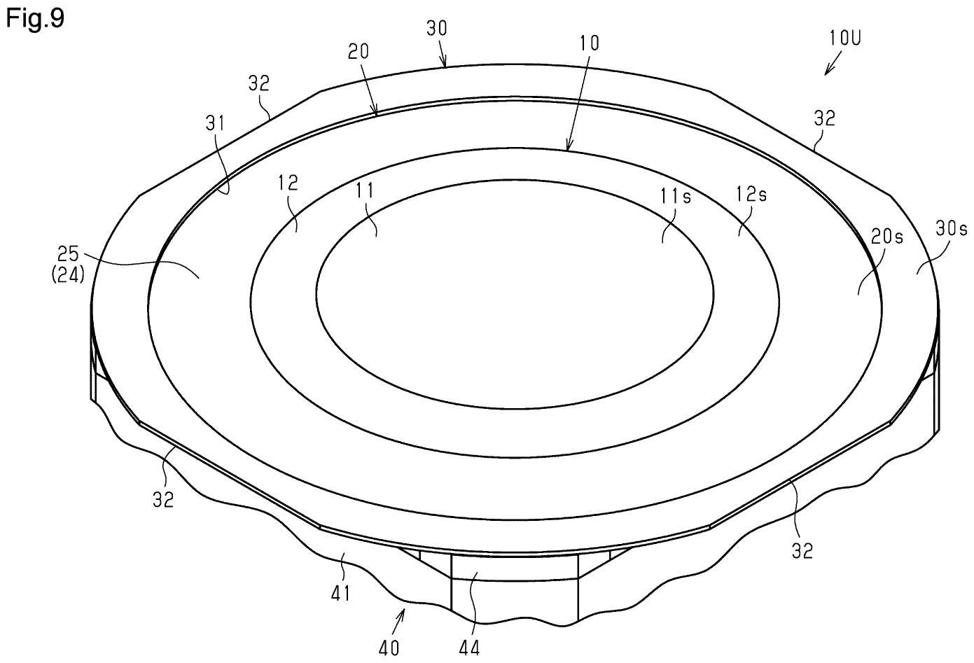

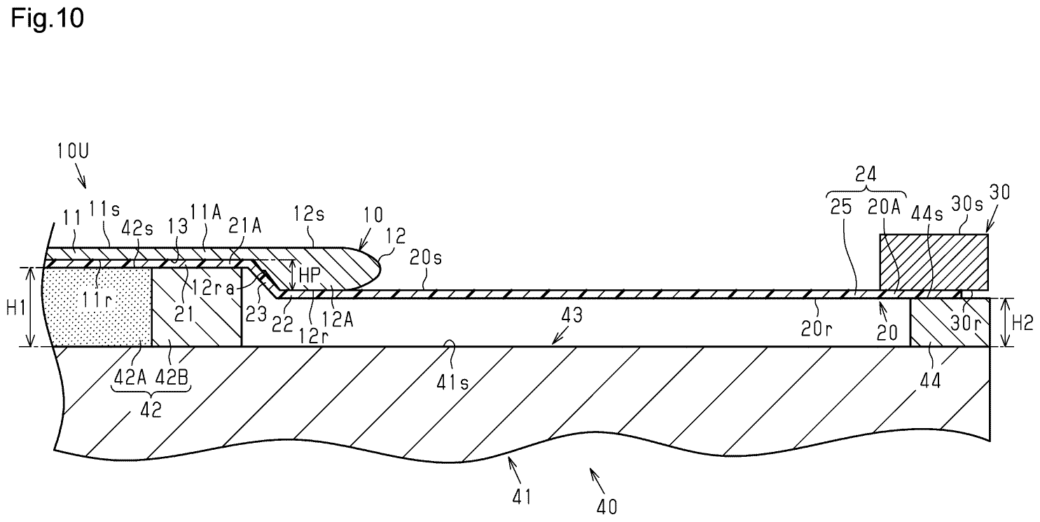

FIG. 9 shows a state in which the wafer unit 10U is set on the processing device 40. FIG. 10 is an enlarged cross-sectional view showing the rim 12 and its surrounding with the wafer unit 10U set on the processing device 40.

Referring to FIG. 9, the setting step is performed after the tape adhering step to set the wafer unit 10U on the processing device 40. More specifically, the setting step sets the wafer unit 10U on the base 41 so that the main body 11 of the semiconductor wafer 10 is supported by the support surface 42s of the stage 42. In one example, the setting step sets the semiconductor wafer 10 on the base 41 so that the main body 11 of the semiconductor wafer 10 is supported by the stage 42 and the frame 30 is supported by the outer portion 43. In further detail, the setting step includes setting the semiconductor wafer 10 on the base 41 so that the main body 11 of the semiconductor wafer 10 is supported by the stage 42 and the frame 30 is supported by the spacer 44.

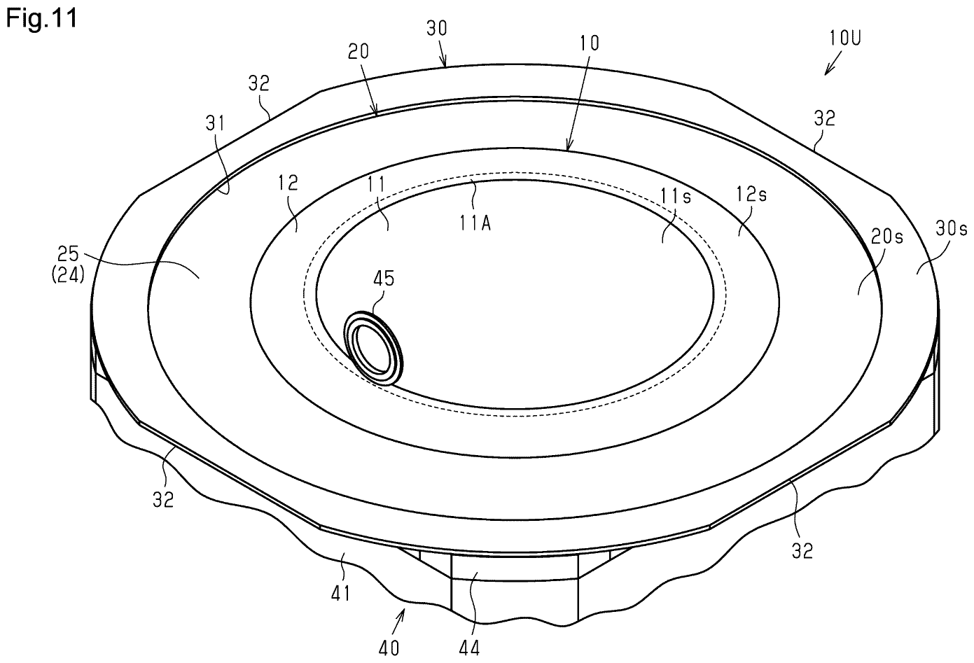

As shown in FIG. 11, in the setting step, the wafer unit 10U is set on the stage 42 so that the second surface 20r of the dicing tape 20 at the main body adhering portion 21 contacts the support surface 42s of the stage 42. In further detail, most of the main body adhering portion 21 of the dicing tape 20 contacts the suction portion 42A, and an outer circumferential edge 21A of the main body adhering portion 21 contacts the surrounding portion 42B. Thus, the suction portion 42A supports the main body 11 of the semiconductor wafer 10, and the surrounding portion 42B supports an edge portion 11A of the main body 11. The edge portion 11A of the main body 11 is the part of the main body 11 located outward from the suction portion 42A of the stage 42. Thus, the edge portion 11A of the main body 11 may be referred to as the outer circumferential portion of the main body 11. In this manner, the stage 42 supports the main body 11. In the present embodiment, the outer circumferential edge of the edge portion 11A of the main body 11 is located outward from the surrounding portion 42B.

As shown in FIG. 10, the rim 12 of the semiconductor wafer 10 is located outward from the stage 42. The sloped portion 23 and the rim adhering portion 22 of the dicing tape 20 are both located outward from the stage 42 and thus do not contact the support surface 42s of the stage 42. The rim adhering portion 22 is located closer to the head surface 41s of the base 41 than the main body adhering portion 21. In other words, the rim adhering portion 22 is located closer to the head surface 41s of the base 41 than the support surface 42s of the stage 42. In addition, the extended portion 24 of the dicing tape 20 is also located outward from the stage 42. Thus, the extended portion 24 does not contact the support surface 42s of the stage 42. The extended portion 24 is located closer to the head surface 41s of the base 41 than the main body adhering portion 21. In other words, the extended portion 24 is located closer to the head surface 41s of the base 41 than the support surface 42s of the stage 42.

As shown in FIG. 10, each spacer 44 is located outward from the semiconductor wafer 10. In the present embodiment, each spacer 44 is distanced apart from the rim 12 of the semiconductor wafer 10 on the outer portion 43. In other words, the stage 42 is separated from each spacer 44 at a part lower than the rim 12. Thus, the part lower than the rim 12 is located between the stage 42 and each spacer 44.

A gap is formed between the rim adhering portion 22 of the dicing tape 20 and the base 41. More specifically, the second surface 20r of the rim adhering portion 22 is located upward from the head surface 41s of the base 41. Thus, in the setting step, the wafer unit 10U is set on the stage 42 so that the semiconductor wafer 10 is supported by the stage 42 with the rim 12 of the semiconductor wafer 10 and the rim adhering portion 22 of the dicing tape 20 both being held in air in an elevated position. In the setting step, the semiconductor wafer 10 is set on the base 41 so that the main body 11 is supported by the stage 42 with the projection 12A of the rim 12 separated from the surface of the outer portion 43 of the base 41 (head surface 41s of base 41).

The height H1 of the support surface 42s of the stage 42 is greater than a projecting length HP of the projection 12A of the rim 12. In other words, the difference in height between the support surface 42s of the stage 42 and the head surface 41s of the base 41 (head surface of outer portion 43) is greater than the projecting length HP of the projection 12A of the rim 12. Thus, as shown in FIG. 10, the second surface 12r of the rim 12 is located upward from the head surface 41s of the base 41 (head surface of outer portion 43). In addition, the second surface 20r of the rim adhering portion 22 is located upward from the head surface 41s of the base 41 (head surface of outer portion 43). Consequently, a gap is formed in the vertical direction between the rim adhering portion 22 and the head surface 41s of the base 41 (head surface of outer portion 43). The projecting length HP of the projection 12A is the distance in the thickness direction of the main body 11 between the second surface 11r of the main body 11 and the second surface 12r of the projection 12A. The height H1 of the support surface 42s of the stage 42 is set in this manner so that the second surface 20r of the rim adhering portion 22 is located upward from the head surface 41s of the base 41.

In the present embodiment, the difference between the height H1 of the support surface 42s of the stage 42 and the height H2 of the upper surface 44s of the spacer 44 (H1-H2) is less than the projecting length HP of the projection 12A of the rim 12. In other words, the difference between the vertical position of the support surface 42s of the stage 42 and the vertical position of the upper surface 44s of the spacer 44 is less than the projecting length HP of the projection 12A of the rim 12. The difference between the height H1 of the support surface 42s of the stage 42 and the height H2 of the upper surface 44s of the spacer 44 (H1-H2) may be changed freely. In one example, the difference between the height H1 of the support surface 42s of the stage 42 and the height H2 of the upper surface 44s of the spacer 44 (H1-H2) may be greater than or equal to the projecting length HP of the projection 12A of the rim 12.

As shown in FIG. 10, in the setting step, the semiconductor wafer 10 is set on the base 41 so that the frame 30 is supported by the spacers 44. That is, the frame 30 is supported by the outer portion 43 on the spacers 44. In the present embodiment, each spacer 44 is located only at a position corresponding to the frame 30. Thus, no part of the spacers 44 of the present embodiment extends inward from the frame 30 and no part of the spacers 44 is located inward from the frame 30. The frame 30 is arranged on the spacers 44 so that the second surface 30r of the frame 30 contacts the upper surface 44s of each spacer 44. In the present embodiment, the edge portion 20A of the dicing tape 20 is arranged on the spacers 44.

The tape outer portion 25 is maintained in an elevated position without being supported by the spacer 44 and the stage 42. Thus, a gap is formed between the tape outer portion 25 and the head surface 41s of the base 41 (head surface of outer portion 43). The tape outer portion 25 is located upward from the head surface 41s of the base 41.

In one example, the height H2 of the upper surface 44s of each spacer 44 and the height H1 of the support surface 42s of the stage 42 are both set so that the extended portion 24 of the dicing tape 20 extends in a horizontal direction, which is orthogonal to the vertical direction, when the semiconductor wafer 10 is set on the stage 42 and the frame 30 is set on the spacer 44. Thus, the distance in the vertical direction between the head surface 41s of the base 41 and the second surface 20r of the rim adhering portion 22 is equal to the height H2 of the upper surface 44s of each spacer 44.

The height H2 of the upper surface 44s of each spacer 44 and the height H1 of the support surface 42s of the stage 42 may each be set so that the extended portion 24 of the dicing tape 20 is inclined relative to the horizontal direction in a state in which the wafer unit 10U is set on the stage 42 and the frame 30 is set on the spacer 44. Thus, the height H2 of the upper surface 44s of the spacer 44 and the height H1 of the support surface 42s of the stage 42 may each be set so that the distance in the vertical direction between the head surface 41s of the base 41 and the second surface 20r of the rim adhering portion 22 differs from the height H2 of the upper surface 44s of the spacer 44.

In this case, the radial length LP of the tape outer portion 25 of the dicing tape 20 (refer to FIG. 5) is greater than the separated amount of the second surface 20r of the rim adhering portion 22 from the upper surface 44s of the spacer 44 in the vertical direction. In one example, the radial length LP of the tape outer portion 25 is approximately 25 mm, and the separated amount is between 100 μm and 300 inclusive. Thus, the radial length LP of the tape outer portion 25 is ten times or greater than the separation length. The radial length LP of the tape outer portion 25 may be changed freely, for example, between 20 mm and 80 mm, inclusive.

Cutting Step

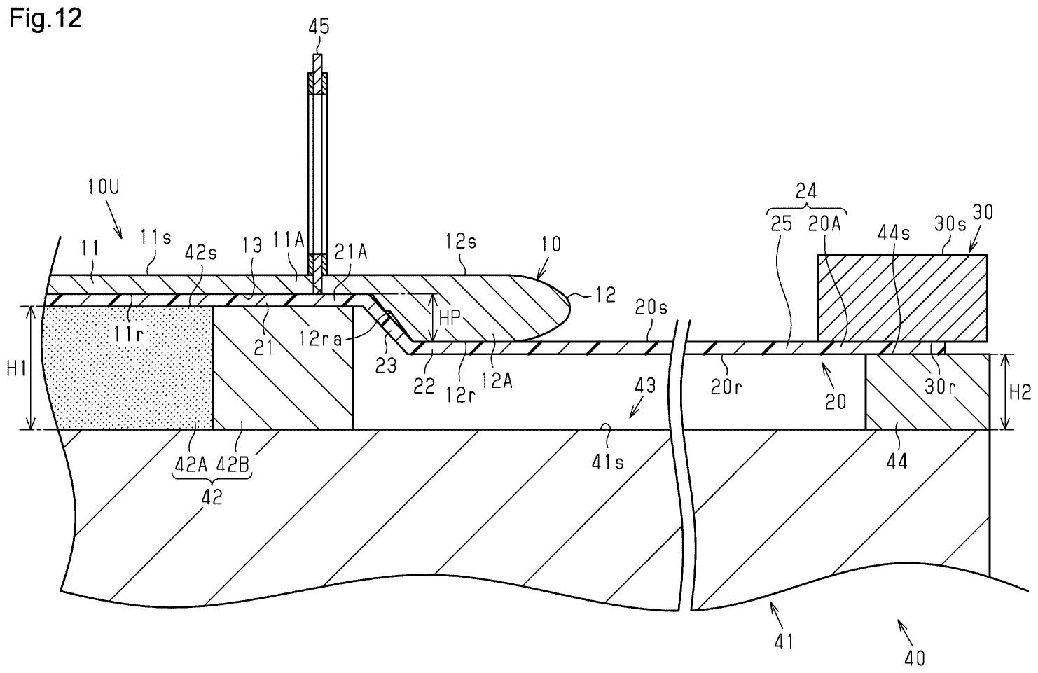

FIG. 11 shows the semiconductor wafer 10 being cut by the processing device 40. FIG. 12 is an enlarged cross-sectional view showing the rim 12 and its surrounding in a state in which the processing device 40 is cutting the semiconductor wafer 10.

As shown in FIG. 11, the cutting step is performed after the setting step to cut away the rim 12 from the main body 11 of the semiconductor wafer 10 with the processing device 40. More specifically, the cutting step separates the main body 11 and the rim 12 by cutting the edge portion 11A of the main body 11 in a state in which the semiconductor wafer 10 is supported by the stage 42 (refer to FIG. 12). In the present embodiment, a dicing blade 45 is used in the cutting step to cut the semiconductor wafer 10. In further detail, the dicing blade 45 is used to cut the semiconductor wafer 10 from the first surface his of the main body 11 when the base 41 is set on the wafer unit 10U.

In one example, as shown in FIG. 12, a suction unit (not shown) of the processing device 40 is first used to suction the main body adhering portion 21 toward the suction portion 42A. As a result, the second surface 20r of the main body adhering portion 21 comes into contact with the support surface 42s of the suction portion 42A. The rim 12 and the rim adhering portion 22 are maintained in an elevated position as described above. That is, the rim 12 and the rim adhering portion 22 contact neither the stage 42 nor the spacer 44. Thus, in the cutting step, a gap is formed between the rim adhering portion 22 and the head surface 41s of the base 41 (head surface of outer portion 43) in the direction orthogonal to the head surface 41s of the base 41 (head surface of outer portion 43). The direction orthogonal to the head surface 41s of the base 41 (surface of outer portion 43) is the thickness direction of the main body 11. In the present embodiment, the direction orthogonal to the head surface 41s of the base 41 (surface of outer portion 43) is the vertical direction. A gap is formed in the vertical direction between the part of the rim adhering portion 22 facing the head surface 41s of the base 41 in the vertical direction and the head surface 41s of the base 41 throughout the circumferential direction of the dicing tape 20. In the cutting step, the tape outer portion 25 is maintained in an elevated position without being supported by the stage 42 or the spacer 44.

Then, the edge portion 11A of the main body 11 is cut by the dicing blade 45 from the first surface 11s of the main body 11. The edge portion 11A that is cut is a part of the edge portion 11A supported by the surrounding portion 42B of the stage 42. This cuts the rim 12 from the main body 11. For example, as shown in FIG. 11, the base 41 is rotated about the center of the stage 42 so that the dicing blade 45 cuts the edge portion 11A of the main body 11 into a circular shape. That is, the semiconductor wafer 10 undergoes a circle-cut. This separates the main body 11 from the rim 12.

Removing Step

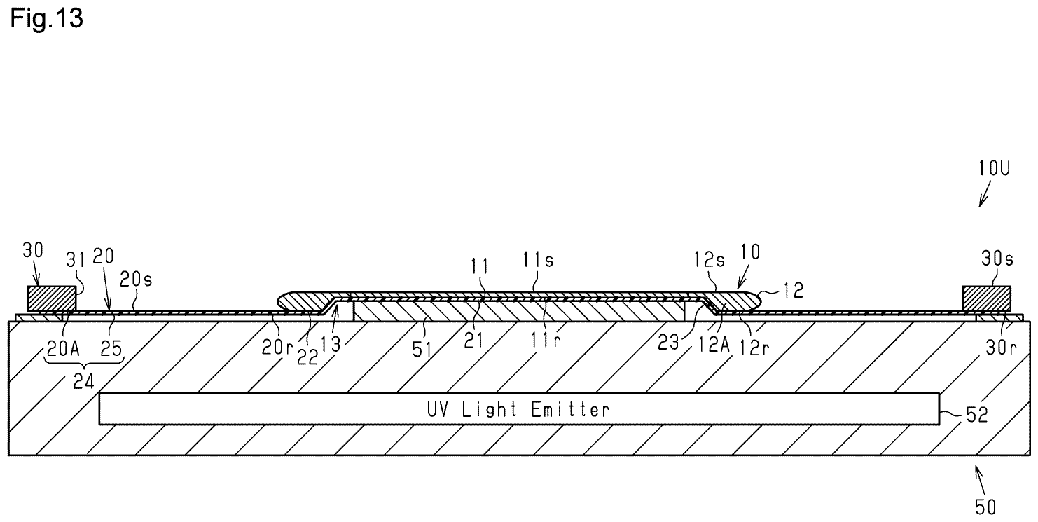

FIG. 13 shows one example of the removing step in which the dicing tape 20 is removed from the main body 11 that was separated from the rim 12.

The removing step is performed after the cutting step to remove the rim 12 from the dicing tape 20. In detail, the wafer unit 10U is first transported from the processing device 40 to a removing device 50. Then, the wafer unit 10U is set so that the second surface 20r of the main body adhering portion 21 of the dicing tape 20 contacts a masking platform 51 of the removing device 50. In this case, the rim 12 and the rim adhering portion 22 are located outward from the masking platform 51. Then, a UV light emitter 52 of the removing device 50 emits light from the lower side in the vertical direction toward the masking platform 51 and the rim adhering portion 22. The UV light is blocked by the masking platform 51 so as not to be emitted toward the main body 11 and be emitted toward only the rim adhering portion 22. This allows the rim 12 to be removed from the rim adhering portion 22. Then, the rim 12, which has been cut away from the main body 11, is removed from the rim adhering portion 22 by a clamp (not shown) of the removing device 50. As a result, the semiconductor wafer 10 is left with only the main body 11.

In this manner, when shifting from the cutting step to the removing step, the semiconductor wafer 10 continues to face the same side in the thickness direction of the main body 11. That is, the recess 13 of the semiconductor wafer 10 continues to face the vertically lower direction in both the cutting step and the removing step.

Singulating Step

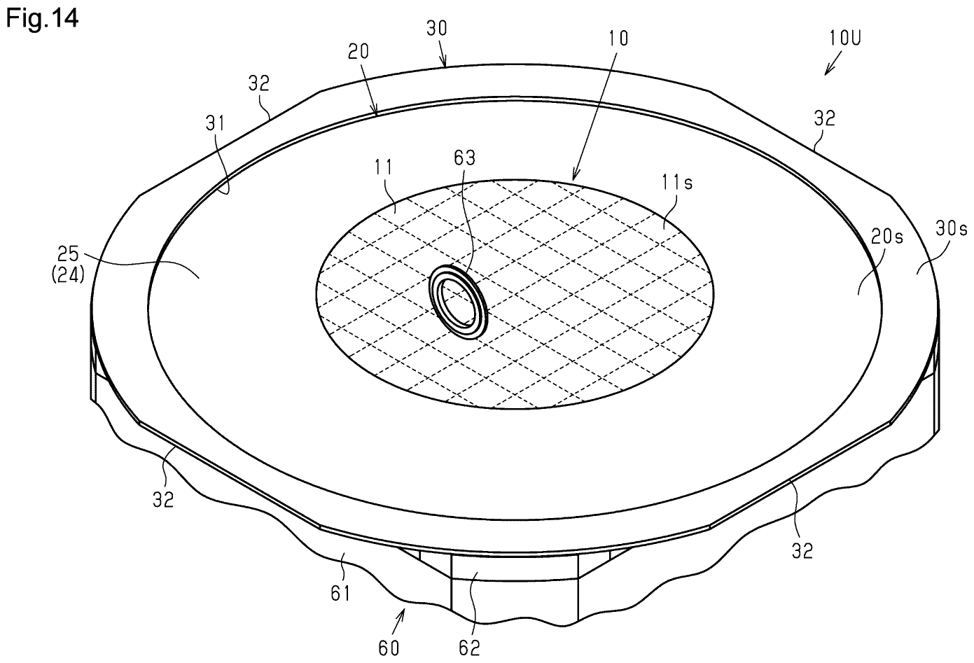

FIG. 14 is a perspective view showing one example of the singulating step in a state in which the wafer unit 10U is set on a dicing device 60.

In the same manner as the processing device 40, the dicing device 60 includes a base 61 and a dicing blade 63 that dices the semiconductor wafer 10. The base 61 includes a stage (not shown), which supports the semiconductor wafer 10, and spacers 62, which support the frame 30. The positional relationship of the base 61 and the wafer unit 10U is the same as that of the base 41 and the wafer unit 10U in the processing device 40. Thus, there is no need to reverse the semiconductor wafer 10.

The singulating step is performed after the removing step to dice the semiconductor wafer 10 into predetermined chip dimensions. In the singulating step, the dicing blade 63 dices the main body 11 of the semiconductor wafer 10. More specifically, the wafer unit 10U is transported from the removing device 50 (refer to FIG. 13) to the dicing device 60. Then, the wafer unit 10U is set so that the second surface 20r of the main body adhering portion 21 of the dicing tape 20 (refer to FIG. 10) contacts the stage of the dicing device 60, and so that the second surface 30r of the frame 30 (refer to FIG. 10) contacts the spacers 62. Next, the dicing blade 63 dices the semiconductor wafer 10 from the first surface 11s of the main body 11 of the semiconductor wafer 10.

In this manner, when shifting from the removing step to the singulating step, the semiconductor wafer 10 continues to face the same side in the thickness direction of the main body 11. That is, the second surface 11r of the semiconductor wafer 10 continues to face the vertically lower direction in both the removing step and the singulating step. Thus, the semiconductor wafer 10 is cut from the first surface 11s of the main body 11 in both the cutting step and the singulating step.

Operation

The operation of the present embodiment will now be described.

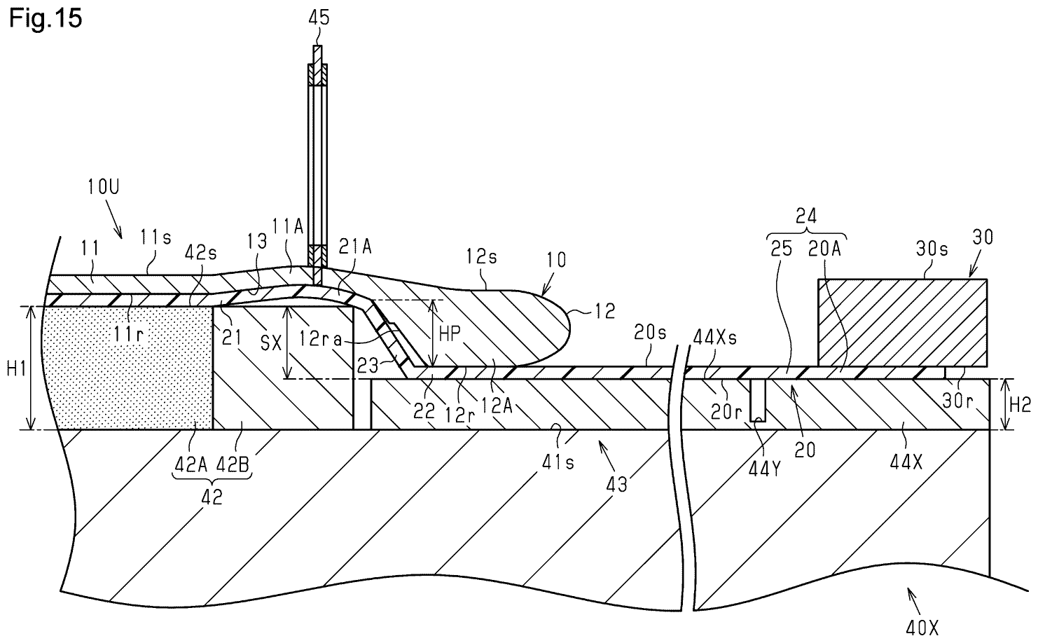

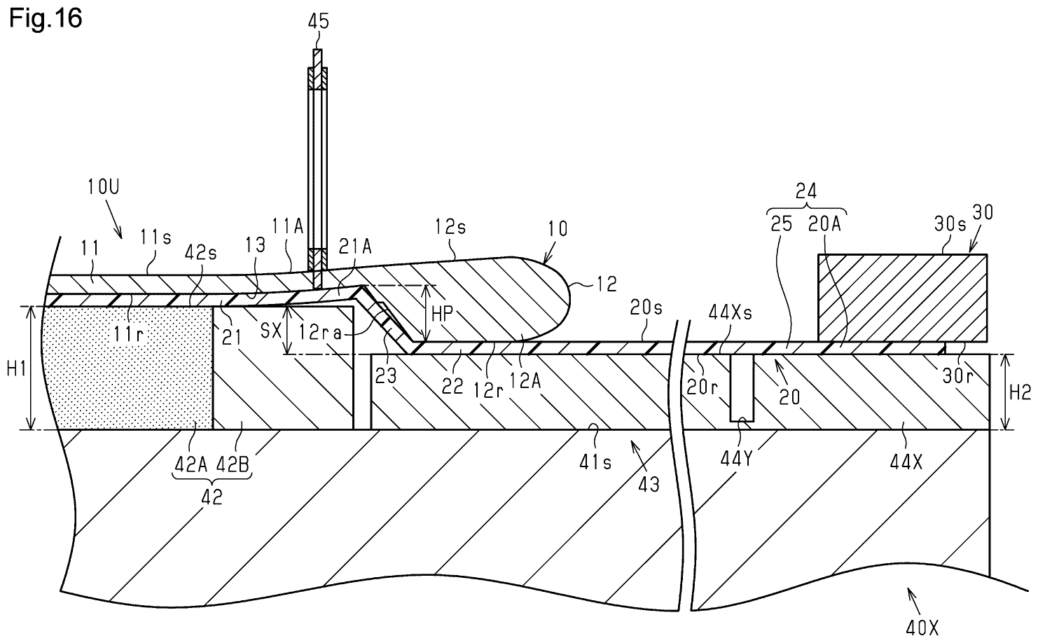

FIGS. 15 and 16 are diagrams illustrating a cutting step of the semiconductor wafer 10 in comparative examples. In a processing device 40X used in the cutting step of the semiconductor wafer 10 in the comparative examples of FIGS. 15 and 16, a spacer 44X is arranged adjacent to the stage 42. Thus, as viewed in the thickness direction of the main body 11, the spacer 44X extends to a position where it overlaps the rim 12.

In the cutting step of the semiconductor wafer 10 in the comparative examples of FIGS. 15 and 16, a suction hole 44Y in the spacer 44X suctions the dicing tape 20 onto the spacer 44X. Thus, in the cutting step of the semiconductor wafer 10 in the comparative example of FIGS. 15 and 16, the rim adhering portion 22 of the dicing tape 20 is in contact with the spacer 44X.

FIG. 15 shows a case in which the projecting length HP of the projection 12A at the rim 12 of the semiconductor wafer 10 is smaller than a step SX that is formed by an upper surface 44Xs of the spacer 44X and the support surface 42s of the stage 42. The step SX corresponds to the difference in height between the upper surface 44Xs of the spacer 44X and the support surface 42s of the stage 42 in the vertical direction.

As shown in FIG. 15, the extended portion 24 of the dicing tape 20 is suctioned by the suction hole 44Y onto the spacer 44X. Thus, the extended portion 24 is in contact with the upper surface 44Xs of the spacer 44X. This produces unnecessary stress that acts on the semiconductor wafer 10. More specifically, the rim adhering portion 22 is drawn toward the spacer 44X. This deforms the rim 12 of the semiconductor wafer 10 toward the spacer 44X. The surrounding portion 42B of the stage 42 is not suctioned to the edge portion 11A of the main body 11. Thus, the outer circumferential edge 21A of the main body adhering portion 21 is elevated to a position separated from the support surface 42s of the surrounding portion 42B. That is, the edge portion 11A of the main body 11 is deformed so as to project upwardly. In this state, when the edge portion 11A of the main body 11 is cut with the dicing blade 45, the part of the main body 11 inward from the edge portion 11A may be damaged. Damage to the main body 11 means cracking, chipping, or fracturing of the main body 11.

FIG. 16 shows a case in which the projecting length HP of the projection 12A at the rim 12 of the semiconductor wafer 10 is larger than the step SX formed by the spacer 44X and the stage 42. In the same manner as FIG. 15, the suction hole 44Y of the spacer 44X suctions the extended portion 24 of the dicing tape 20 onto the spacer 44X. Thus, the extended portion 24 is in contact with the upper surface 44Xs of the spacer 44X. This draws the rim adhering portion 22 and the rim 12 toward the spacer 44X and produces unnecessary stress acting on the semiconductor wafer 10. Further, the projecting length HP of the projection 12A is larger than the step SX. Thus, in a state in which the rim adhering portion 22 and the rim 12 are contacting the spacer 44X, the reaction force of the spacer 44X elevates the edge portion 11A of the main body 11 and the outer circumferential edge 21A of the main body adhering portion 21 to a position separated from the surrounding portion 42B of the stage 42. In this state, when the edge portion 11A of the main body 11 is cut with the dicing blade 45, the part of the main body 11 inward from the edge portion 11A may be damaged.

To avoid such elevation of the edge portion 11A of the main body 11 and the outer circumferential edge 21A of the main body adhering portion 21 in the cutting step of the semiconductor wafer 10 in the comparative examples, the height of the spacer 44X has to be set so that the projecting length HP of the projection 12A becomes equal to the step SX. The height of the spacer 44X is the difference between the position of the upper surface 44Xs of the spacer 44X and the position of the head surface 41s of the base 41. Consequently, multiple types of the spacer 44X have to be prepared when the projecting length HP of the projection 12A differs between different types of the semiconductor wafer 10. This will be burdensome because the spacer 44X will have to be selected in accordance with the semiconductor wafer 10. Further, one may inadvertently select a spacer 44X that is not in accordance with the semiconductor wafer 10.

In the present embodiment, when the rim 12 and the rim adhering portion 22 are both maintained in an elevated position, the rim 12 and the rim adhering portion 22 both do not contact either one of the stage 42 and the spacer 44. In addition, the processing device 40 differs from the processing device 40X of the comparative examples shown in FIGS. 15 and 16 in that it does not include the suction hole 44Y. Thus, the extended portion 24 is free from a force that results in the extended portion 24 contacting the spacer 44. Consequently, the semiconductor wafer 10 will not be subject to unnecessary stress applied to the semiconductor wafer 10 like in the cutting step of the comparative example. This avoids a situation in which the edge portion 11A of the main body 11 and the outer circumferential edge 21A of the main body adhering portion 21 are both elevated to a position separated from the surrounding portion 42B of the stage 42. Thus, there is no need to prepare different spacers 44 in accordance with each type of semiconductor wafer 10.

Advantages

The present embodiment has the advantages described below.
(1) The method for processing the semiconductor wafer 10 includes the setting step and the cutting step. The setting step sets the semiconductor wafer 10, to which the dicing tape 20 is adhered, on the stage 42 so that the main body 11 of the semiconductor wafer 10 is supported by the stage 42 of the processing device 40 in a state in which the rim adhering portion 22 of the dicing tape 20 and the rim 12 of the semiconductor wafer 10 are both maintained in an elevated position. The cutting step, which is performed after the setting step, separates the rim 12 from the main body 11 in a state in which the main body adhering portion 21 of the dicing tape 20 is suctioned by the suction portion 42A of the stage 42.

With this configuration, unnecessary stress will not be applied to the semiconductor wafer 10 by the rim 12 in the cutting step. Thus, when cutting the semiconductor wafer 10, cracking, chipping, or fracturing will not occur in the main body 11 of the semiconductor wafer 10.
(2) The difference in height between the support surface 42s of the stage 42 of the processing device 40 and the head surface 41s of the base 41 (surface of outer portion 43) is greater than the projecting length HP of the projection 12A at the rim 12 of the semiconductor wafer 10.

This configuration ensures that the rim 12 is separated from the head surface 41s of the base 41 when the wafer unit 10U is set on the support surface 42s of the stage 42, that is, when the main body 11 of the semiconductor wafer 10 is supported by the stage 42.
(3) In the processing device 40, the stage 42 and the spacers 44 rise from the base 41. The height H2 of the upper surface 44s of each spacer 44 is lower than the height H1 of the support surface 42s of the stage 42. The spacer 44 is configured to allow the frame 30, to which the dicing tape 20 is adhered, to be set thereon.

In a state in which the main body 11 of the semiconductor wafer 10 is set on the stage 42 and the frame 30 is set on the spacer 44, the second surface 30r of the frame 30 will not be located upward in the vertical direction from the second surface 12r of the rim 12. Thus, unnecessary stress will not act on the semiconductor wafer 10 in the cutting step.
(4) In the cutting step, a gap is formed in the vertical direction between the rim adhering portion 22 and the head surface 41s of the base 41.

With this configuration, in the cutting step, the rim adhering portion 22 is maintained in an elevated position and separated from the base 41. This will limit the application of unnecessary stress to the semiconductor wafer 10 that would be caused by the rim adhering portion 22.
(5) The tape outer portion 25 of the dicing tape 20 is maintained in an elevated position without being supported by the stage 42 or the spacer 44.

This configuration limits the application of unnecessary stress to the semiconductor wafer 10 that would be caused by the tape outer portion 25.
(6) The radial length LP of the tape outer portion 25 of the dicing tape 20 is greater than the width WR of the rim 12.

This configuration reduces the stress acting on the semiconductor wafer 10 that would be caused when the difference between the height H1 of the support surface 42s of the stage 42 and the height H2 of the upper surface 44s of the spacer 44 (H1-H2) deviates from a preset value. Thus, when cutting the semiconductor wafer 10, cracking, chipping, or fracturing will not occur in the main body 11 of the semiconductor wafer 10.
(7) The method for processing the semiconductor wafer 10 further includes the singulating step. The singulating step, which is performed after the removing step that removes the rim 12 cut from the semiconductor wafer 10 in the cutting step, dices the semiconductor wafer 10 into predetermined chip dimensions. The cutting step and the singulating step both cut the semiconductor wafer 10 from the first surface 11s of the main body 11.

With this configuration, in the cutting step and the singulating step, the semiconductor wafer 10 is not reversed in the thickness direction of the main body 11. Thus, there is no need to add a means or step for reversing the semiconductor wafer 10 with respect to the thickness direction of the main body 11. This avoids an increase in facility costs and limits the processing steps of the semiconductor wafer 10 in number.

### MODIFIED EXAMPLES

The embodiment described above exemplifies, without any intention to limit, an applicable form of a method for processing a semiconductor device according to this disclosure. The method for processing a semiconductor device in accordance with this disclosure may be modified from the embodiment described above. For example, the configuration in the above embodiment may be replaced, changed, or omitted in part or include an additional element. The modified examples described below may be combined as long as there is no technical contradiction. In the modified examples described hereafter, same reference characters are given to those components that are the same as the corresponding components of the above embodiments. Such components will not be described in detail.

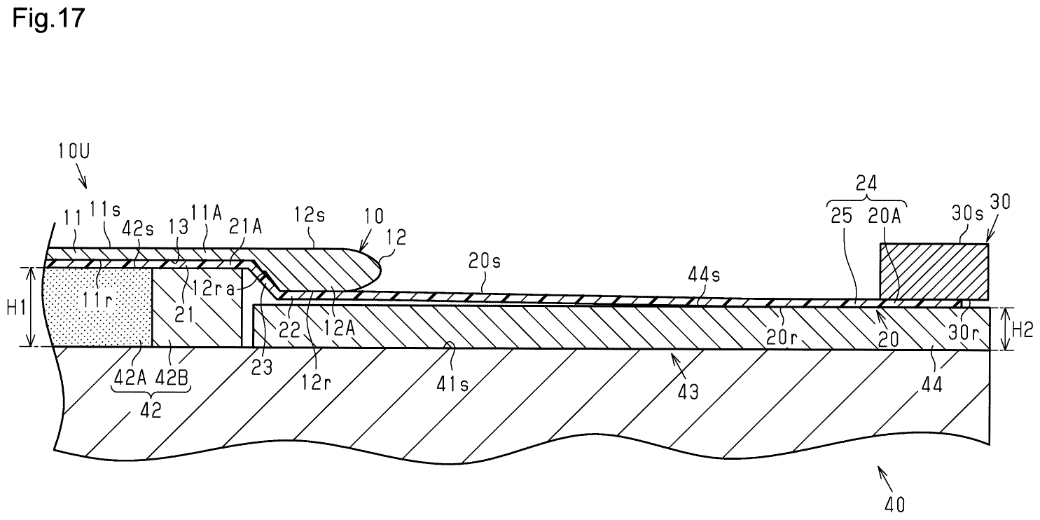

In the above embodiment, each spacer 44 may have any shape. In one example, as shown in FIG. 17, each spacer 44 may be located adjacent to the stage 42. In the illustrated example, each spacer 44 extends from a position corresponding to the rim 12 of the semiconductor wafer 10 to a position corresponding to the frame 30 in plan view. Thus, each spacer 44 is located in the vertical direction between the rim 12 of the semiconductor wafer 10 and the head surface 41s of the base 41 (surface of outer portion 43). In this case, a gap is formed in the vertical direction during the cutting step between the rim adhering portion 22 of the dicing tape 20 and each spacer 44. The configuration has the same advantages as the above embodiment.

In the modified example shown in FIG. 17, the spacer 44 may be looped in plan view. In this case, the spacer 44 extends throughout the entire outer portion 43 of the base 41.

In the above embodiment, the radial length LP of the tape outer portion 25 of the dicing tape 20 may be varied freely. In one example, the radial length LP of the tape outer portion 25 may be less than or equal to the width WR of the rim 12.

In the above embodiment, at least part of the tape outer portion 25 of the dicing tape 20 may be supported by the spacers 44. In this case, each spacer 44 only contacts the tape outer portion 25 and does not suction the tape outer portion 25. This differs from the spacer 44X of the comparative example that performs suctioning with the suction hole 44Y.

In the above embodiment, the frame 30 may have any shape. In one example, the flat portions 32 may be omitted from the frame 30. In this case, the frame 30 is ring-shaped as viewed in the thickness direction of the main body 11.

In the above embodiment, the four spacers 44 do not have to be located at the four corners of the base 41 and may be located anywhere.

In the above embodiment, there may be any number of spacers 44.

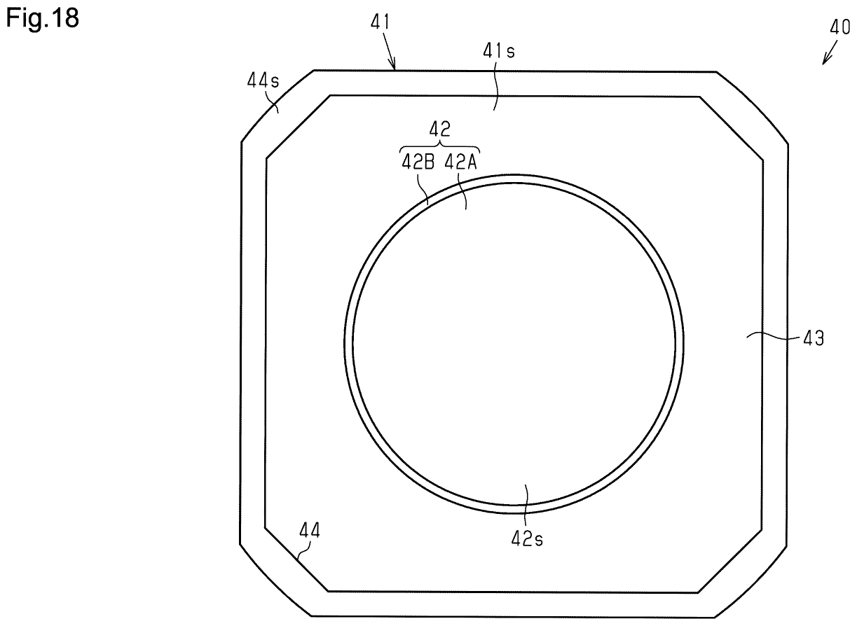

In the above embodiment, the spacer 44 may have any shape. In one example, as shown in FIG. 18, the spacer 44 may be looped in plan view. The spacer 44 is spaced apart outwardly from the stage 42. The spacer 44 surrounds the stage 42. In the illustrated example, the spacer 44 is shaped in a looped manner and extends along the edge of the base 41.

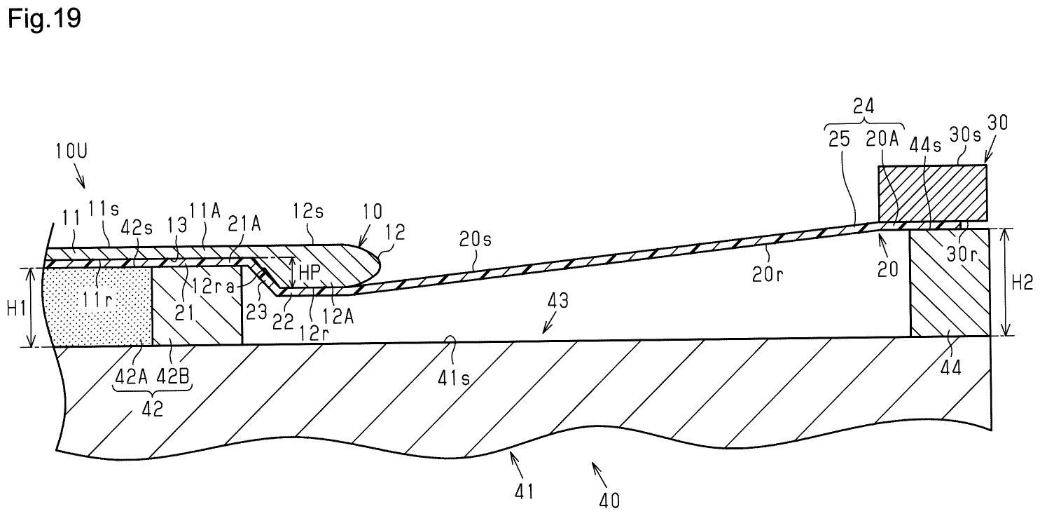

In the above embodiment, the spacers 44 may have any height. In one example, the spacers 44 and the stage 42 may be located at the same height. Further, in one example, under the condition that unnecessary stress will not act on the semiconductor wafer 10 during the setting step and the cutting step, as shown in FIG. 19, the height of the spacers 44 from the head surface 41s of the base 41 in the vertical direction may be greater than that of the stage 42. In other words, the spacers 44 may be higher than the stage 42. That is, the height H2 of the upper surface 44s of each spacer 44 may be greater than the height H1 of the support surface 42s of the stage 42. In the illustrated example, the upper surface 44s of the spacer 44 and the first surface 11s of the main body 11 of the semiconductor wafer 10 are located at the same height.

In this case, the tape outer portion 25 of the dicing tape 20 is inclined so that the head surface 41s of the base 41 becomes farther as the spacer 44 becomes closer. In the same manner as the above embodiment, the edge portion 20A of the dicing tape 20 is held between the upper surface 44s of the spacer 44 and the frame 30.

In the above embodiment, the spacers 44 may be omitted from the processing device 40. In this case, during the setting step, the frame 30 may be held in contact with the head surface 41s of the base 41 (surface of outer portion 43). That is, the setting step sets the semiconductor wafer 10 on the base 41 so that the main body 11 of the semiconductor wafer 10 is supported by the stage 42, and so that the frame 30 is supported by the outer portion 43. Further, the cutting step separates the main body 11 and the rim 12 by cutting the edge portion 11A of the main body 11 in a state in which the semiconductor wafer 10 is set on the base 41 so that the main body 11 of the semiconductor wafer 10 is supported by the stage 42, and so that the frame 30 is supported by the outer portion 43.

In the cutting step of the above embodiment, the dicing blade 45 is used to cut the edge portion 11A from the main body 11 of the semiconductor wafer 10. The edge portion 11A, however, does not have to be cut in such a manner. For example, instead of the dicing blade 45, a laser may be used to cut the edge portion 11A. In the same manner, a laser may be used instead of the dicing blade 63 during the singulating step to dice the main body 11.

In the above embodiment, the singulating step may be omitted from the method for processing the semiconductor wafer 10. The removing step may be omitted from the method for processing the semiconductor wafer 10.

In this specification, the word “on” includes the meaning of “above” in addition to the meaning of “on” unless otherwise described in the context. Accordingly, the phrase of “A formed on B” means that A contacts B and is directly arranged on B, and may also mean, as a modified example, that A is arranged above B without contacting B. Thus, the word “on” will also allow for a structure in which another member is formed between A and B.

### CLAUSES

Technical concepts that can be understood from the above embodiment and the modified examples will now be described. The reference characters used to denote elements of the embodiments are shown in parenthesis for the corresponding elements of the clauses described below. The reference characters are given as examples to aid understanding and not intended to limit elements to the elements denoted by the reference characters.

### Clause 1

A method for processing a semiconductor wafer (10), the method including:
preparing a semiconductor wafer (10) including a main body (11) and a rim (12), the main body (11) including a first surface (11s) on which a semiconductor element is formed and a second surface (11r) at an opposite side of the first surface (11s), the rim (12) having a greater thickness than the main body (11), the rim (12) surrounding the main body (11) in a looped manner as viewed in a thickness direction of the main body (11), and the rim (12) including a projection (12A) projecting from the second surface (11r) of the main body (11) opposite the first surface (11s) in the thickness direction;
supporting the semiconductor wafer (10) with a holding tape (20) adhered to the second surface (11r) of the semiconductor wafer (10);
preparing a base (41) including a stage (42) and an outer portion (43), the stage (42) including a support surface (42s) that supports the main body (11), and the outer portion (43) including a head surface (41s) at a lower height than the support surface (42s) of the stage (42);
setting the semiconductor wafer (10), which is supported by the holding tape (20), on the base (41) so that the main body (11) is supported by the support surface (42s) of the stage (42); and
separating the main body (11) and the rim (12) by cutting an edge portion (11A) of the main body (11) in a state in which the main body (11) is supported by the stage (42);
where the setting the semiconductor wafer (10) on the base (41) includes setting the semiconductor wafer (10) on the base (41) so that the main body (11) is supported by the stage (42) in a state in which the projection (12A) is separated from the head surface (41s) of the outer portion (43) of the base (41).

### Clause 2

The method according to clause 1, where a difference (H1) in height between the support surface (42s) of the stage (42) and the head surface (41s) of the outer portion (43) is greater than a projecting length (HP) of the projection (12A) of the rim (12).

### Clause 3

The method according to clause 1 or 2, where:
the holding tape (20) includes an edge portion (20A) fixed to a looped frame (30);
the frame (30) includes an inner wall shaped and sized to allow for accommodation of the semiconductor wafer (10);
the supporting the semiconductor wafer (10) with the holding tape (20) includes supporting the semiconductor wafer (10) with the holding tape (20) that is fixed to the frame (30); and
the setting the semiconductor wafer (10) on the base (41) includes setting the semiconductor wafer (10) on the base (41) so that the main body (11) is supported by the stage (42) and the frame (30) is supported by the outer portion (43).

### Clause 4

The method according to clause 3, where:
the outer portion (43) of the base (41) allows a spacer (44) having a predetermined thickness to be set thereon;
in a state in which the spacer (44) is set on the outer portion (43), an upper surface (44s) of the spacer (44) is located at a lower height than the support surface (42s) of the stage (42); and
the setting the semiconductor wafer (10) on the base (41) includes setting the semiconductor wafer (10) on the base (41) so that the main body (11) is supported by the stage (42) and the frame (30) is supported by the spacer (44).

### Clause 5

The method according to clause 4, where:
in the separating the main body (11) and the rim (12), a gap extends in a direction orthogonal to the head surface (41s) of the outer portion (43) of the base (41) between the outer portion (43) of the base (41) and a rim adhering portion (22) of the holding tape (20) that is adhered to the rim (12); and
the spacer (44) is located outward from the rim (12) on the outer portion (43).

### Clause 6

The method according to clause 5, where the spacer (44) is located only at a position corresponding to the frame (30).

### Clause 7

The method according to clause 6, where the spacer (44) is looped as viewed in the thickness direction.

### Clause 8

The method according to clause 6, where the spacer (44) is formed at spaced intervals as viewed in the thickness direction.

### Clause 9

The method according to clause 4, where:
the spacer (44) is located between the rim (12) and the outer portion (43); and
in the separating the main body (11) and the rim (12), a gap extends in a direction orthogonal to the head surface (41s) of the outer portion (43) of the base (41) between the spacer (44) and a rim adhering portion (22) of the holding tape (20) that is adhered to the rim (12).

### Clause 10

The method according to clause 9, where the spacer (44) extends from a position corresponding to the rim (12) to a position corresponding to the frame (30) and is looped as viewed in the thickness direction.

### Clause 11

The method according to any one of clauses 4 to 10, where in the separating the main body (11) and the rim (12), a part (25) of the holding tape (20) between the rim (12) and the frame (30) is maintained in an elevated position without being supported by the stage (42) or the spacer (44).

### Clause 12

The method according to any one of clauses 3 to 11, where:
the holding tape (20) is circular; and
a part (25) of the holding tape (20) between the rim (12) and the frame (30) has a radial length (LP) that is greater than a width (WR) of the rim (12).

### Clause 13

The method according to any one of clauses 1 to 12, where:
the holding tape (20) is a dicing tape; and
in the separating the main body (11) and the rim (12), the semiconductor wafer (10) is cut with a dicing blade (45).

### Clause 14

The method according to clause 13, where in the separating the main body (11) and
the rim (12), the semiconductor wafer (10) is cut in a state in which the stage (42) is suctioning the holding tape (20) and the outer portion (43) is not suctioning the holding tape (20).

### Clause 15

The method according to any one of clauses 1 to 14, further including separating the rim (12) from the holding tape (20) after the separating of the main body (11) and the holding tape (20).

### Clause 16

The method according to clause 15, further including dicing the semiconductor wafer (10) into predetermined chip dimensions after the separating of the rim (12) from the holding tape (20).

### Clause 17

The method according to clause 16, where the semiconductor wafer (10) is cut from the first surface (11s) in both the separating the main body (11) and the rim (12) and the dicing the semiconductor wafer (10) into predetermined chip dimensions.

### Clause 18

The method according to clause 9, where the spacer (44) extends from a position corresponding to the rim (12) to a position corresponding to the frame (30) and is formed at spaced intervals as viewed in the thickness direction.

### Clause 19

The method according to clause 10 or 18, where a difference in height from the base (41) between the support surface (42s) of the stage (42) and the upper surface (44s) of the spacer (44) is greater than a projecting length (HP) of the projection (12A) of the rim (12).

### REFERENCE SIGNS LIST

10U) wafer unit
10) semiconductor wafer
11) main body
11A) edge portion
11s) first surface
11r) second surface
12) rim
12A) projection
12s) first surface
12r) second surface
12ra) sloped surface
13) recess
20) dicing tape (holding tape)
20A) edge portion
20s) first surface
20r) second surface
21) main body adhering portion
21A) outer circumferential edge
22) rim adhering portion
23) sloped portion
24) extended portion
25) tape outer portion
30) frame
30s) first surface
30r) second surface
31) open portion
32) flat portion
40) processing device
41) base
41s) head surface
42) stage
42A) suction portion
42B) surrounding portion
42s) support surface
43) outer portion
44) spacer
44s) upper surface
45) dicing blade
50) removing device
51) masking platform
52) UV light emitter
60) dicing device
61) base
62) spacer
63) dicing blade
H1) stage support surface height
H2) spacer upper surface height
HP) projecting length
LP) tape outer portion radial length
WR) rim width

1. A method for processing a semiconductor wafer, the method comprising:
preparing a semiconductor wafer including a main body and a rim, the main body including a first surface on which a semiconductor element is formed and a second surface at an opposite side of the first surface, the rim having a greater thickness than the main body, the rim surrounding the main body in a looped manner as viewed in a thickness direction of the main body, and the rim including a projection projecting from the second surface of the main body opposite the first surface in the thickness direction;
supporting the semiconductor wafer with a holding tape adhered to the second surface of the semiconductor wafer;
preparing a base including a stage and an outer portion, the stage including a support surface that supports the main body, and the outer portion including a head surface at a lower height than the support surface of the stage;
setting the semiconductor wafer, which is supported by the holding tape, on the base so that the main body is supported by the support surface of the stage; and
separating the main body and the rim by cutting an edge portion of the main body in a state in which the main body is supported by the stage;
wherein the setting the semiconductor wafer on the base includes setting the semiconductor wafer on the base so that the main body is supported by the stage in a state in which the projection is separated from the head surface of the outer portion of the base.

2. The method according to claim 1, wherein a difference in height between the support surface of the stage and the head surface of the outer portion is greater than a projecting length of the projection of the rim.

3. The method according to claim 1, wherein:
the holding tape includes an edge portion fixed to a looped frame;
the frame includes an inner wall shaped and sized to allow for accommodation of the semiconductor wafer;
the supporting the semiconductor wafer with the holding tape includes supporting the semiconductor wafer with the holding tape that is fixed to the frame; and
the setting the semiconductor wafer on the base includes setting the semiconductor wafer on the base so that the main body is supported by the stage and the frame is supported by the outer portion.

4. The method according to claim 3, wherein:
the outer portion of the base allows a spacer having a predetermined thickness to be set thereon;
in a state in which the spacer is set on the outer portion, an upper surface of the spacer is located at a lower height than the support surface of the stage; and
the setting the semiconductor wafer on the base includes setting the semiconductor wafer on the base so that the main body is supported by the stage and the frame is supported by the spacer.

5. The method according to claim 4, wherein:
in the separating the main body and the rim, a gap extends in a direction orthogonal to the head surface of the outer portion of the base between the outer portion of the base and a rim adhering portion of the holding tape that is adhered to the rim; and
the spacer is located outward from the rim on the outer portion.

6. The method according to claim 5, wherein the spacer is located only at a position corresponding to the frame.

7. The method according to claim 6, wherein the spacer is looped as viewed in the thickness direction.

8. The method according to claim 6, wherein the spacer is formed at spaced intervals as viewed in the thickness direction.

9. The method according to claim 4, wherein:
the spacer is located between the rim and the outer portion; and
in the separating the main body and the rim, a gap extends in a direction orthogonal to the head surface of the outer portion of the base between the spacer and a rim adhering portion of the holding tape that is adhered to the rim.

10. The method according to claim 9, wherein the spacer extends from a position corresponding to the rim to a position corresponding to the frame and is looped as viewed in the thickness direction.

11. The method according to claim 4, wherein in the separating the main body and the rim, a part of the holding tape between the rim and the frame is maintained in an elevated position without being supported by the stage or the spacer.

12. The method according to claim 3, wherein:
the holding tape is circular; and
a part of the holding tape between the rim and the frame has a radial length that is greater than a width of the rim.

13. The method according to claim 1, wherein:
the holding tape is a dicing tape; and
in the separating the main body and the rim, the semiconductor wafer is cut with a dicing blade.

14. The method according to claim 13, wherein in the separating the main body and the rim, the semiconductor wafer is cut in a state in which the stage is suctioning the holding tape and the outer portion is not suctioning the holding tape.

15. The method according to claim 1, further comprising separating the rim from the holding tape after the separating of the main body and the holding tape.

16. The method according to claim 15, further comprising dicing the semiconductor wafer into predetermined chip dimensions after the separating of the rim from the holding tape.

17. The method according to claim 16, wherein the semiconductor wafer is cut from the first surface in both the separating the main body and the rim and the dicing the semiconductor wafer into predetermined chip dimensions.
